(19) United States
(12) Patent Application Publication
(10) Pub. No.: US 2024/0363620 A1
(43) Pub. Date: Oct. 31, 2024

(54) SEMICONDUCTOR DEVICE

(71) Applicant: FUJI ELECTRIC CO., LTD., Kawasaki-shi (JP)

(72) Inventors: Kiminori TANAKA, Matsumoto-city (JP); Masaharu YAMAJI, Matsumoto-city (JP)

(73) Assignee: FUJI ELECTRIC CO., LTD., Kawasaki-shi (JP)

(21) Appl. No.: 18/592,013

(22) Filed: Feb. 29, 2024

(30) Foreign Application Priority Data
Apr. 27, 2023 (JP) 2023-073568

(51) Int. Cl. H01L 27/02

(52) U.S. Cl. CPC H01L 27/0274

(57) ABSTRACT

A semiconductor device includes: a semiconductor base body of a first conductivity-type; a first well region of a second conductivity-type provided at an upper part of the semiconductor base body; a protection element provided in the first well region and including transistors arranged at several stages each including a carrier supply region and a gate electrode mutually short-circuited; a VCC pad provided on a top surface side of the semiconductor base body; and an AGND pad provided on the top surface side of the semiconductor base body, wherein a carrier reception region of the transistor at a frontmost stage included in the protection element is connected to the VCC pad, and the carrier supply region and the gate electrode of the transistor at a rearmost stage included in the protection element are connected to the AGND pad via a first wire.

### CROSS-REFERENCE TO RELATED APPLICATION

This application claims benefit of priority under 35 USC 119 based on Japanese Patent Application No. 2023-073568 filed on Apr. 27, 2023, the entire contents of which are incorporated by reference herein.

### BACKGROUND OF THE INVENTION

### 1. Field of the Invention

The present invention relates to semiconductor devices.

### 2. Description of the Related Art

JPH10-32260A discloses an input protection element having a configuration in which a protection element of a P-channel MOS transistor and a protection element of an N-channel MOS transistor are connected in series between a power-supply line and an input terminal connected to an input side of a target element to be protected.

Conventional switching control circuits include protection elements for protecting an internal circuit against a surge such as electrostatic discharge (ESD) or a high voltage.

If a voltage applied to a terminal connected to such a protection element steeply increases, the protection element could cause a malfunction, leading to a flow of a large amount of current accordingly.

### SUMMARY OF THE INVENTION

In view of the foregoing problems, the present invention provides a semiconductor device having a configuration capable of avoiding a malfunction of a protection element when a voltage of a terminal connected to the protection element steeply increases.

An aspect of the present invention inheres in a semiconductor device including: a semiconductor base body of a first conductivity-type; a first well region of a second conductivity-type provided at an upper part of the semiconductor base body; a protection element provided in the first well region and including transistors arranged at several stages each including a carrier supply region and a gate electrode mutually short-circuited; a first pad provided on a top surface side of the semiconductor base body; and a second pad provided on the top surface side of the semiconductor base body, wherein a carrier reception region of the transistor at a frontmost stage included in the protection element is connected to the first pad, and the carrier supply region and the gate electrode of the transistor at a rearmost stage included in the protection element are connected to the second pad via a first wire.

### BRIEF DESCRIPTION OF THE DRAWINGS

FIG. 1 is a circuit diagram of a semiconductor device according to a first embodiment;

FIG. 2 is a circuit diagram of a protection element according to the first embodiment;

FIG. 3 is another circuit diagram of the protection element according to the first embodiment;

FIG. 4 is a circuit diagram of a driving regulator according to the first embodiment;

FIG. 5 is a plan view illustrating the semiconductor device according to the first embodiment;

FIG. 6 is an enlarged plan view of region A in FIG. 5;

FIG. 7 is a cross-sectional view taken along line A-A′ in FIG. 6;

FIG. 8 is a plan view illustrating a semiconductor device of a comparative example;

FIG. 9 is a cross-sectional view taken along line A-A′ in FIG. 8;

FIG. 10 is another cross-sectional view taken along line A-A′ in FIG. 6;

FIG. 11 is a timing chart for explaining each of the semiconductor device according to the first embodiment and the semiconductor device of the comparative example; and

FIG. 12 is a plan view illustrating a semiconductor device according to a second embodiment.

### DETAILED DESCRIPTION

With reference to the drawings, first and second embodiments of the present invention will be described below.

In the drawings, the same or similar elements are indicated by the same or similar reference numerals. The drawings are schematic, and it should be noted that the relationship between thickness and planer dimensions, the thickness proportion of each layer, and the like are different from real ones. Accordingly, specific thicknesses or dimensions should be determined with reference to the following description. Moreover, in some drawings, portions are illustrated with different dimensional relationships and proportions. The first and second embodiments described below merely illustrate schematically devices and methods for specifying and giving shapes to the technical idea of the present invention, and the span of the technical idea is not limited to materials, shapes, structures, and relative positions of elements described herein.

In the specification, a “carrier supply region” means a semiconductor region which supplies majority carriers as a main current. The carrier supply region is assigned to a semiconductor region which will be a source region in a field-effect transistor (FET) or a static induction transistor (SIT), an emitter region in an insulated-gate bipolar transistor (IGBT), and an anode region in a diode, a static induction (SI) thyristor or a gate turn-off (GTO) thyristor. A “carrier reception region” means a semiconductor region which receive the majority carriers as the main current. The carrier reception region is assigned to a semiconductor region which will be the drain region in the FET or the SIT, the collector region in the IGBT, and the cathode region in the diode, SI thyristor or GTO thyristor.

In the specification, definitions of directions such as an up-and-down direction in the following description are merely definitions for convenience of understanding, and are not intended to limit the technical ideas of the present invention. For example, as a matter of course, when the subject is observed while being rotated by 90°, the subject is understood by converting the up-and-down direction into the right-and-left direction. When the subject is observed while being rotated by 180°, the subject is understood by inverting the up-and-down direction.

In the specification, there is exemplified a case where a first conductivity-type is a p-type and a second conductivity-type is an n-type. However, the relationship of the conductivity-types may be inverted to set the first conductivity-type to the n-type and the second conductivity-type to the p-type. Further, a semiconductor region denoted by the symbol “n” or “p” attached with “+” indicates that such semiconductor region has a relatively high impurity concentration as compared to a semiconductor region denoted by the symbol “n” or “p” without “+”. A semiconductor region denoted by the symbol “n” or “p” attached with “−” indicates that such semiconductor region has a relatively low impurity concentration as compared to a semiconductor region denoted by the symbol “n” or “p” without “−”. However, even when the semiconductor regions are denoted by the same reference symbols “n” and “n”, it is not indicated that the semiconductor regions have exactly the same impurity concentration. Moreover, the members and the regions that are limited by adding “first conductivity-type” and “second conductivity-type” in the following description indicate the members and the regions formed of semiconductor materials without particular obvious limitations.

### First Embodiment

### <Circuit of Semiconductor Device>

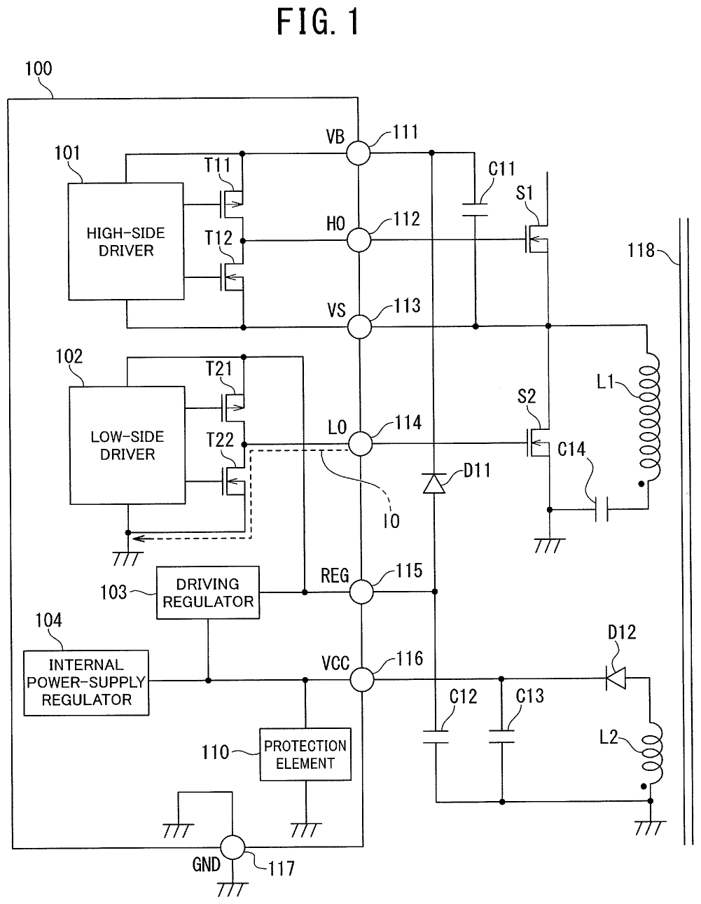

A semiconductor device (a semiconductor integrated circuit) according to a first embodiment is illustrated with a switching power-supply circuit of an LCC current resonant type that generates an output voltage at a target level for a load from a predetermined input voltage. The semiconductor device according to the first embodiment includes switching elements S1 and S2, a transformer 118, and a switching control circuit (a control circuit) 100, as illustrated in FIG. 1.

The semiconductor device according to the first embodiment may include all of the elements illustrated in FIG. 1, or may include part of these elements instead. For example, the semiconductor device according to the first embodiment may only include the control circuit 100 without the switching elements S1 and S2 or the transformer 118. Alternately, the semiconductor device according to the first embodiment may include the switching elements S1 and S2 and the control circuit 100 without the transformer 118.

The switching element S1 is a power transistor on the high-potential side which is a high-side power transistor. The switching element S2 is a power transistor on the low-potential side which is a low-side power transistor. While FIG. 1 illustrates a case in which the switching elements S1 and S2 are each an n-channel MOSFET, the respective switching elements S1 and S2 may be a p-channel MOSFET or an IGBT instead. The switching elements S1 and S2 are connected in series so as to implement a half-bridge circuit. An input potential is applied to a drain of the switching element S1. A drain of the switching element S2 is connected to a source of the switching element S1. A source of the switching element S2 is grounded.

The transformer 118 includes a primary coil L1 and an auxiliary coil L2 electromagnetically coupled to the primary coil L1 with the same polarity. One end of the primary coil L1 is connected to a connection point between the source of the switching element S1 and the drain of the switching element S2. The other end of the primary coil L1 is connected to the source of the switching element S2 via a capacitor C14 and is also grounded. A voltage at the respective ends of the primary coil L1 varies depending on the switching operation of the respective switching elements S1 and S2.

The auxiliary coil L2 causes a voltage in accordance with a change in the voltage at the respective ends of the primary coil L1. Although not illustrated in FIG. 1, the transformer 118 further includes a secondary coil electromagnetically coupled to the primary coil L1 with a different polarity. The secondary coil causes a voltage in accordance with a change in the voltage at the respective ends of the primary coil L1. The control circuit 100 controls the switching operation of the respective switching elements S1 and S2. The control circuit 100 includes a VB terminal 111, an HO terminal 112, a VS terminal 113, an LO terminal 114, an REG terminal 115, a VCC terminal 116, and a GND terminal 117.

The VB terminal 111 is a terminal to which a power-supply potential VB is applied. One end of a capacitor C11 is connected to the VB terminal 111. The capacitor C11 functions so as to stabilize the power-supply potential VB. A cathode of a diode D11 is also connected to the VB terminal 111.

The HO terminal 112 is a terminal to which a drive signal HO for driving the high-side switching element S1 is output. A gate of the switching element S1 is connected to the HO terminal 112.

The VS terminal 113 is a terminal to which a reference potential VS lower than the power-supply potential VB is applied. A ground potential is applied to the VS terminal 113 as the reference potential VS when the switching element S2 is turned ON, and an input potential is applied to the VS terminal 113 as the reference potential VS when the switching element S1 is turned ON. The other end of the capacitor C11 and a connection point between the source of the switching element S1 and the drain of the switching element S2 are connected to the VS terminal 113.

The LO terminal 114 is a terminal to which a drive signal LO for driving the low-side switching element S2 is output. A gate of the switching element S2 is connected to the LO terminal 114.

The REG terminal 115 is a terminal that outputs a power-supply potential REG lower than the power-supply potential VB. One end of a capacitor C12 and an anode of the diode D11 are connected to the REG terminal 115. The capacitor C12 functions so as to stabilize the power-supply potential REG. The diode D11 charges the capacitor C11 with electricity based on the power-supply potential REG when the switching element S2 is turned ON and the reference potential VS is led to be the ground voltage.

The VCC terminal 116 is a terminal to which a power-supply potential VCC lower than the power-supply potential VB corresponding to the voltage from the auxiliary coil L2 is applied. A cathode of the diode D12 and one end of the capacitor C13 are connected to the VCC terminal 116. One end of the auxiliary coil L2 is connected to an anode of the diode D12. The other end of the capacitor C13 is connected with the other end of the capacitor C12 and the other end of the auxiliary coil L2, and is also grounded.

The GND terminal 117 is a terminal to which a ground potential GND lower than the power-supply potential VB, the power-supply potential REG, the power-supply potential VCC, and the reference potential VS is applied. The GND terminal 117 is connected to a casing of a device provided with the control circuit 100, for example.

The control circuit 100 includes output-stage elements T11 and T12, and a high-potential-side drive circuit (a high-side driver) 101 for driving the respective output-stage elements T11 and T12. The output-stage element T11 is a p-channel MOSFET and the output-stage element T12 is an n-channel MOSFET so as to implement a CMOS circuit together.

Agate of the output-stage element T11 is connected to the high-side driver 101. A source of the output-stage element T11 is connected to the VB terminal 111 and the high-side driver 101. A drain of the output-stage element T11 is connected to the HO terminal 112 and a drain of the output-stage element T12. A gate of the output-stage element T12 is connected to the high-side driver 101. A source of the output-stage element T12 is connected to the VS terminal 113 and the high-side driver 101.

The high-side driver 101 operates by use of the reference potential VS applied to the VS terminal 113 as a reference potential and by use of the power-supply potential VB applied to the VB terminal 111 as a power-supply potential. The high-side driver 101 outputs drive signals for driving the output-stage elements T11 and T12 to the respective gates of the output-stage elements T11 and T12.

The control circuit 100 further includes output-stage elements T21 and T22, and a low-potential-side drive circuit (a low-side driver) 102 for driving the respective output-stage elements T21 and T22. The output-stage element T21 is a p-channel MOSFET and the output-stage element T22 is an n-channel MOSFET so as to implement a CMOS circuit together.

A gate of the output-stage element T21 is connected to the low-side driver 102. A source of the output-stage element T21 is connected to the REG terminal 115 and the low-side driver 102. A drain of the output-stage element T21 is connected to the LO terminal 114 and a drain of the output-stage element T22. A gate of the output-stage element T22 is connected to the low-side driver 102. A source of the output-stage element T22 is grounded.

The low-side driver 102 operates by use of the ground potential applied to the GND terminal 117 as a reference potential and by use of the power-supply potential REG applied to the REG terminal 115 as a power-supply potential. The low-side driver 102 outputs drive signals for driving the output-stage elements T21 and T22 to the respective gates of the output-stage elements T21 and T22.

The control circuit 100 further includes a protection element 110, a regulator (a driving regulator) 103 used for the low-side driver 102, a regulator (an internal power-supply regulator) 104 used for an internal power supply.

One end of the protection element 110 is connected to the VCC terminal 116, the driving regulator 103, and the internal power-supply regulator 104, while the other end is grounded. The protection element 110 extracts a surge such as ESD or a high voltage when applied to the VCC terminal 116 so as to protect the internal circuit including the driving regulator 103 and the internal power-supply regulator 104 connected to the VCC terminal 116.

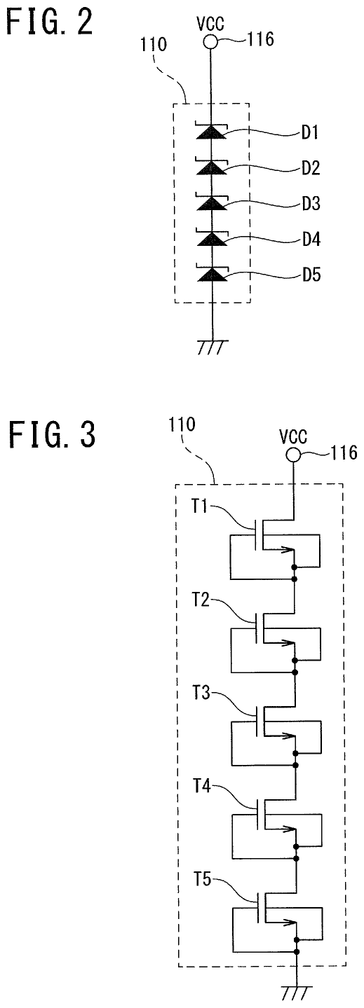

The protection element 110 includes diodes D1 to D5 arranged at plural (five) stages connected in series, as illustrated in FIG. 2. The number of the diodes (the number of the stages) included in the protection element 110 is not limited to this case as illustrated, and is only required to be two or more. The breakdown voltage is higher as the number of the diodes (the stages) is greater. A cathode of the diode D1 at the frontmost stage (at the first stage) is connected to the VCC terminal 116. An anode of the diode D5 at the rearmost stage (at the fifth stage) is grounded.

The diodes D1 to D5 included in the protection element 110 respectively correspond to transistors T1 to T5 provided at plural (five) stages, as illustrated in FIG. 3. The transistors T1 to T5 are each an n-channel MOSFET. The transistors T1 to T5 each have a gate and a source that are mutually short-circuited, so as to serve as the diodes D1 to D5 respectively illustrated in FIG. 2.

A drain of the transistor T1 at the frontmost stage (at the first stage) is connected to the VCC terminal 116. The source of the transistor T1 at the first stage is connected to a drain of the transistor T2 at the second stage. The source of the transistor T2 at the second stage is connected to a drain of the transistor T3 at the third stage. The source of the transistor T3 at the third stage is connected to a drain of the transistor T4 at the fourth stage. The source of the transistor T4 at the fourth stage is connected to a drain of the transistor T5 at the fifth stage. The source of the transistor T5 at the fifth stage is grounded.

The driving regulator 103 illustrated in FIG. 1 is connected to the REG terminal 115, the source of the output-stage element T21, and the low-side driver 102. The driving regulator 103 is also connected to the VCC terminal 116, the internal power-supply regulator 104, and the protection element 110.

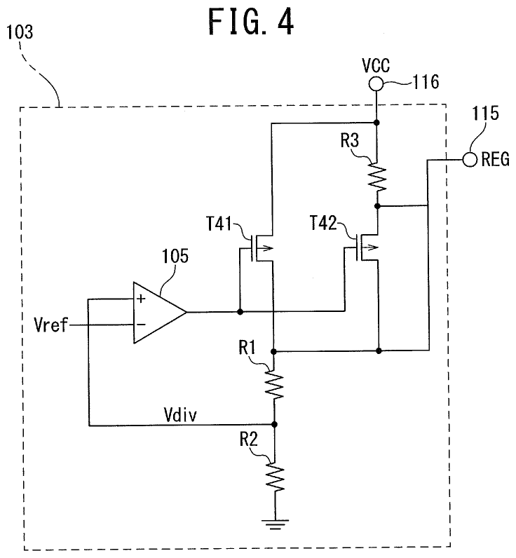

The driving regulator 103 causes a voltage drop of the power-supply potential VCC so as to output the power-supply potential REG lower than the power-supply potential VCC. As illustrated in FIG. 4, the driving regulator 103 includes an operational amplifier 105, transistors T41 and T42, and resistors R1 to R3. The transistors T41 and T42 are each a p-channel MOSFET, for example.

The operational amplifier 105 outputs a gate potential for the transistor T41 so that a potential Vdiv at the connection point between the respective resistors R1 and R2 is led to be a potential Vref applied to an inverting input. The output of the gate potential made by the operational amplifier 105 for the transistor T41 is based on the potential Vdiv applied to a non-inverting input.

The transistor T41 outputs the power-supply potential REG caused by the voltage drop of the power-supply potential VCC in accordance with the gate potential from the operational amplifier 105. The resistors R1 and R2 are connected in series. The power-supply potential REG is applied to one end of the connected resistors R1 and R2, while the other end is grounded. The resistors R1 and R2 output the potential Vdiv at the connection point between the resistors R1 and R2.

The transistor T42 leads a current to flow in accordance with the current flowing through the transistor T41. The gate potential of the transistor T41 is applied to a gate of the transistor T42. The power-supply potential VCC is applied to a source of the transistor T42 via the resistor R3. The power-supply potential REG is applied to a drain of the transistor T42.

The internal power-supply regulator 104 illustrated in FIG. 1 causes a voltage drop of the power-supply potential VCC so as to output a power-supply voltage for the internal power-supply circuit lower than the power-supply potential VCC. The internal power-supply regulator 104 may have substantially the same configuration as the driving regulator 103 illustrated in FIG. 4.

### <Configuration of Semiconductor Device>

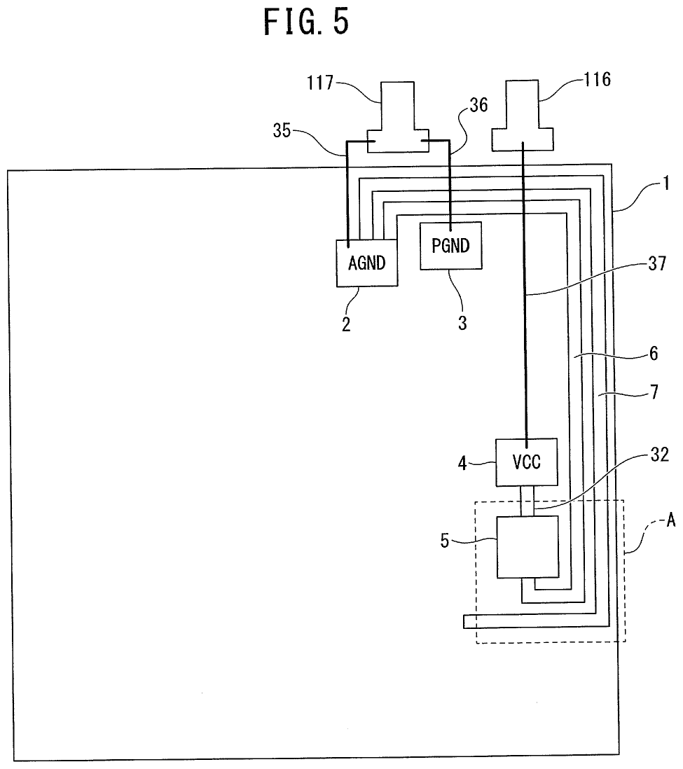

FIG. 5 illustrates a planar layout of a semiconductor chip 1 in which the elements included in the control circuit 100 of the semiconductor device according to the first embodiment are integrated. The semiconductor chip 1 has a substantially rectangular planar pattern. The semiconductor chip 1 includes an analog ground pad (an AGND pad) 2, a power ground pad (a PGND pad) 3, a reference potential pad (a VCC pad) 4, and a protection element 5. FIG. 5 omits the illustration of the elements other than the AGND pad 2, the PGND pad 3, the VCC pad 4, and the protection element 5 for reasons of convenience.

FIG. 5 also illustrates the configuration of the semiconductor device including the control circuit 100 without the switching elements S1 and S2 or the transformer 118 illustrated in FIG. 1. In this case, the VB terminal 111, the HO terminal 112, the VS terminal 113, the LO terminal 114, the REG terminal 115, the VCC terminal 116, and the GND terminal 117 of the control circuit 100 illustrated in FIG. 1 each serve as an external connection terminal packaged in the semiconductor device. FIG. 5 illustrates only the VCC terminal 116 and the GND terminal 117 among the external connection terminals of the control circuit 100. FIG. 5 omits the illustration of the package.

The PGND pad 3 is a pad for ground used only for the low-side driver 102. The low-side driver 102 illustrated in FIG. 1 is connected to the PGND pad 3. The PGND pad 3 is electrically connected to the GND terminal 117 via a bonding wire 36 so that the ground potential GND is applied.

The AGND pad 2 is arranged at a position separated from but adjacent to the PGND pad 3. The AGND pad 2 is a pad for ground used for the elements (for the circuit) other than the low-side driver 102. Examples of the elements of the circuit other than the low-side driver 102 include low breakdown-voltage transistors such as a 5-V breakdown-voltage MOS and resistors. The AGND pad 2 is electrically connected to the GND terminal 117 via a bonding wire 35 so that the ground potential GND is applied. The AGND pad 2 is electrically connected to the PGND pad 3 through the bonding wire 35 connecting the AGND pad 2 and the GND terminal 117, the GND terminal 117, and the bonding wire 36 connecting the GND terminal 117 and the PGND pad 3.

The VCC pad 4 is arranged at a position separated from the AGND pad 2 and the PGND pad 3 and closer to the protection element 5 than the AGND pad 2 and the PGND pad 3. The VCC pad 4 is electrically connected to the VCC terminal 116 via a bonding wire 37 so that the power-supply potential VCC is applied.

The protection element 5 corresponds to the protection element 110 illustrated in FIG. 1. The protection element 5 is connected to the AGND pad 2 via a wire 6, and is connected to the VCC pad 4 via a wire 32. The wire 6 extends along the outer circumference of the semiconductor chip 1. A wire 7 is connected to the AGND pad 2. The wire 7 extends along the outer circumference of the semiconductor chip 1 parallel to the wire 6 to reach a position adjacent to the protection element 5. The wire 6, the wire 7, and the wire 32 are each a wire of metal (a metallic wire) such as copper (Cu) and aluminum (Au).

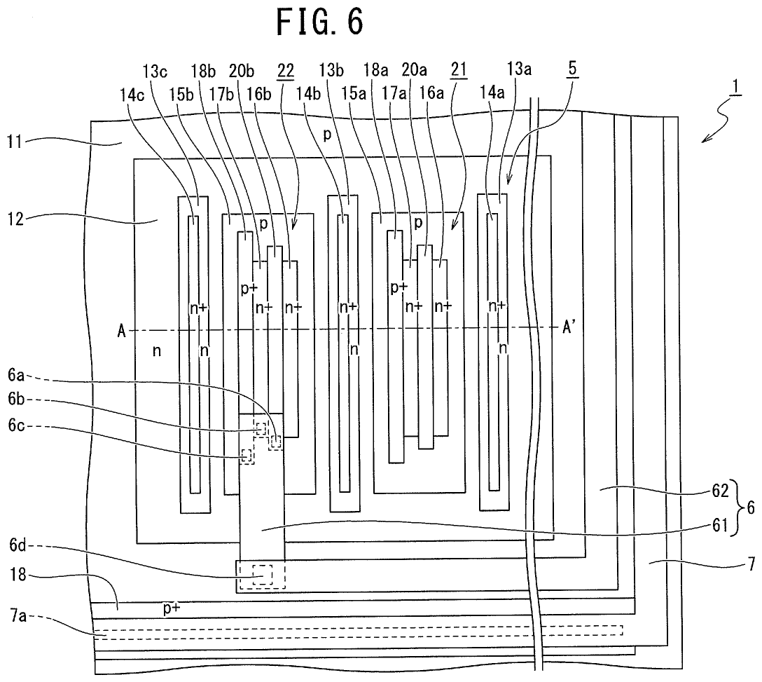

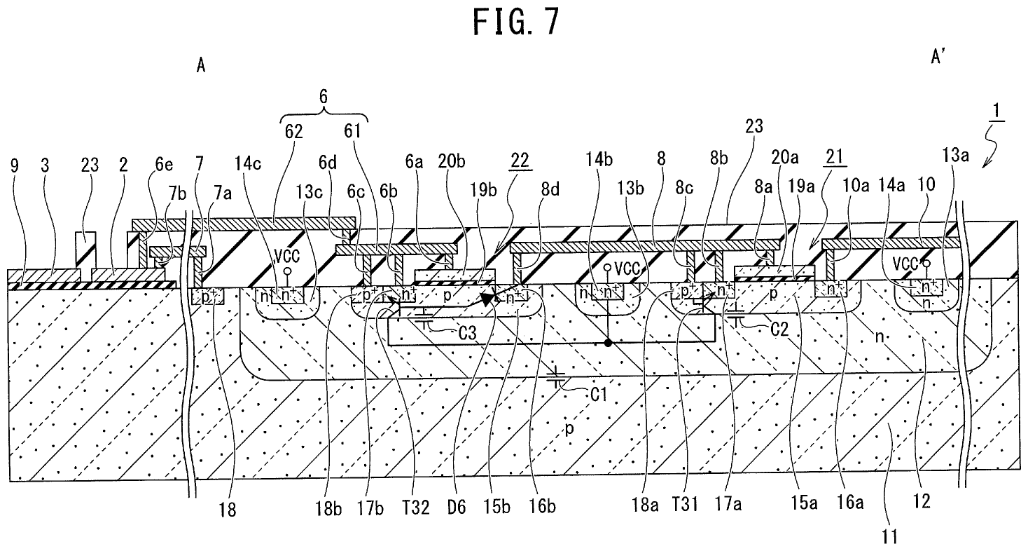

FIG. 6 is an enlarged plan view of region A surrounding the protection element 5 illustrated in FIG. 5, and illustrates only the wire 6 and the wire 7 among the metallic wires. FIG. 7 is a cross-sectional view including a part cross-sectioned along line A-A′ in FIG. 6, including the AGND pad 2 and the PGND pad 3.

The semiconductor chip 1 includes a semiconductor base body 11 of a first conductivity-type (p-type). The semiconductor base body 11 may be connected to the GND terminal 117 illustrated in FIG. 1 so as to be fixed at the ground potential GND. The semiconductor base body 11 may be a silicon (S1) substrate, for example. Alternatively, the semiconductor base body 11 may be a semiconductor substrate including silicon carbide (SiC), gallium nitride (GaN), gallium oxide (Ga₂O₃), gallium arsenide (GaAs), or diamond, for example. Alternatively, the semiconductor base body 11 may be composed of a semiconductor substrate and an epitaxial layer of p-type epitaxially-grown on the semiconductor substrate.

FIG. 7 illustrates the case in which the positions of the respective elements located over the top surface of the semiconductor base body 11 are changed as appropriate from the position of the line A-A′. FIG. 6 and FIG. 7 each omit the illustration of a region provided with the respective transistors corresponding the transistor T1 at the first stage to the transistor T3 at the third stage, among the five-stage transistors T1 to T5 included in the protection element 5 illustrated in FIG. 3, but illustrates a transistor 21 corresponding to the transistor T4 at the fourth stage and a transistor 22 corresponding to the transistor T5 at the fifth stage.

As illustrated in FIG. 6 and FIG. 7, a well region 12 of a second conductivity-type (n-type) is provided on the top surface side (at the upper part) of the semiconductor base body 11. As schematically illustrated in FIG. 6, the semiconductor base body 11 and the well region 12 make up parasitic capacitance C1. As illustrated in FIG. 6, the well region 12 has a substantially rectangular planar pattern.

As illustrated in FIG. 6 and FIG. 7, well regions 15a and 15b of p-type are provided separately from each other on the top surface side (at the upper part) of the well region 12. As schematically illustrated in FIG. 6, the well region 15a and the well region 12 make up parasitic capacitance C2, and the well region 15b and the well region 12 make up parasitic capacitance C3. As illustrated in FIG. 6, the well regions 15a and 15b each have a substantially rectangular planar pattern.

As illustrated in FIG. 6 and FIG. 7, the well region 15a is provided with the transistor 21 at the fourth stage. The transistor 21 includes a carrier reception region (a drain region) 16a of n⁺-type, a carrier supply region (a source region) 17a of n⁺-type, and a contact region 18a of p⁺-type each provided on the top surface side (at the upper part) of the well region 15a. The drain region 16a is located at a position separated from the source region 17a and the contact region 18a. The source region 17a and the contact region 18a are in contact with each other. As schematically illustrated in FIG. 7, the source region 17a, the well region 15a, and the well region 12 implement a parasitic npn bipolar transistor T31.

A gate electrode 20a is provided on the top surface side of the well region 15a located between the drain region 16a and the source region 17a with a gate insulating film 19a interposed. As illustrated in FIG. 6, the drain region 16a, the source region 17a, the contact region 18a, and the gate electrode 20a each have a substantially straight planar pattern so as to extend parallel to each other.

As illustrated in FIG. 6, an insulating film 23 is deposited on the top surface side of the semiconductor base body 11. The drain region 16a of the transistor 21 at the fourth stage is connected to a wire 10 arranged inside the insulating film 23 through a via 10a provided in a contact hole of the insulating film 23. Although not illustrated, a gate electrode, a source region, and a contact region of the transistor at the third stage are connected to the wire 10.

One end of a wire 8 arranged inside the insulating film 23 is connected to the gate electrode 20a, the source region 17a, and the contact region 18a of the transistor 21 at the fourth stage through vias 8a to 8c provided in contact holes of the insulating film 23. The gate electrode 20a, the source region 17a, and the contact region 18a of the transistor 21 at the fourth stage are mutually short-circuited through the vias 8a to 8c and the wire 8. The other end of the wire 8 is connected to a drain region 16b of the transistor 22 at the fifth stage through a via 8d provided in a contact hole of the insulating film 23. FIG. 6 omits the illustration of the insulating film 23, the via 10a, the wire 10, the vias 8a to 8d, and the wire 8.

As illustrated in FIG. 6 and FIG. 7, the well region 15b is provided with the transistor 22 at the fifth stage. The transistor 22 includes a carrier reception region (a drain region) 16b of n⁺-type, a carrier supply region (a source region) 17b of n⁺-type, and a contact region 18b of p⁺-type each provided on the top surface side (at the upper part) of the well region 15b. The drain region 16b is located at a position separated from the source region 17b and the contact region 18b. The source region 17b and the contact region 18b are in contact with each other. As schematically illustrated in FIG. 7, the source region 17b, the well region 15b, and the well region 12 implement a parasitic npn bipolar transistor T32.

A gate electrode 20b is provided on the top surface side of the well region 15b located between the drain region 16b and the source region 17b with a gate insulating film 19b interposed. As illustrated in FIG. 6, the drain region 16b, the source region 17b, the contact region 18b, and the gate electrode 20b each have a substantially straight planar pattern so as to extend parallel to each other.

As illustrated in FIG. 6 and FIG. 7, one end of a lower-layer wiring layer 61 arranged inside the insulating film 23 is connected to the gate electrode 20b, the source region 17b, and the contact region 18b of the transistor 22 at the fifth stage through vias 6a to 6c provided in contact holes of the insulating film 23. The gate electrode 20b, the source region 17b, and the contact region 18b of the transistor 22 at the fifth stage are mutually short-circuited through the vias 6a to 6c and the lower-layer wiring layer 61. The other end of the lower-layer wiring layer 61 is connected to one end of an upper-layer wiring layer 62 provided at a position upper than the lower-layer wiring layer 61 inside the insulating film 23 through a via 6d provided in a contact hole of the insulating film 23. The AGND pad 2 is connected to the other end of the upper-layer wiring layer 62 through a via 6e provided in a contact hole of the insulating film 23.

The wire 6 is composed of the lower-layer wiring layer 61 and the upper-layer wiring layer 62. The wire 6 does not necessarily include both the lower-layer wiring layer 61 and the upper-layer wiring layer 62 having different heights, but may be a single layer having a configuration in which one end is connected to the vias 6a to 6c and the other end is connected to the via 6e.

As illustrated in FIG. 6 and FIG. 7, well regions 13a to 13c of the second conductivity-type (n-type) having a higher impurity concentration than the well region 12 are provided separately from each other on the top surface side (at the upper part) of the well region 12. The well regions 13a and 13b are arranged to interpose the well region 15a. The well regions 13b and 13c are arranged to interpose the well region 15b. As illustrated in FIG. 6, the well regions 13a to 13c each have a substantially straight planar pattern so as to extend parallel to each other. Further, contact regions (pick-up regions) 14a to 14c of the second conductivity-type (n⁺-type) having a higher impurity concentration than the well regions 13a to 13c are provided on the top surface side of the corresponding well regions 13a to 13c. The VCC terminal 116 illustrated in FIG. 1 is connected to the contact regions 14a to 14c so that the power-supply potential VCC is applied.

Although not illustrated, three well regions of n-type provided with the transistors at the first to third stages are provided in the well region 15a on the side opposite to the well region 15b. The transistors at the first to third stages each have a configuration similar to that of each of the transistor 21 at the fourth stage and the transistor 22 at the fifth stage. The drain region of the transistor at the first stage (not illustrated) is connected to the VCC pad 4 via the wire 32 illustrated in FIG. 5 provided inside the insulating film 23 through a via (not illustrated) provided in a contact hole of the insulating film 23. Although not illustrated, the VCC pad 4 is provided on the top surface side of the semiconductor base body 11 with an insulating film interposed.

Further, well regions of n-type similar to the well regions 13a to 13c are provided to interpose the respective transistors at the first to third stages, and contact regions of n⁺-type are further provided on the top surface side of the respective well regions. The n⁺-type contact regions are connected to the VCC terminal 116 illustrated in FIG. 1 so that the power-supply potential VCC is applied.

As illustrated in FIG. 6 and FIG. 7, a substrate contact region 18 of p⁺-type having a higher impurity concentration than the semiconductor base body 11 is provided on the top surface side (at the upper part) of the semiconductor base body 11 separately from the well region 12. The low breakdown-voltage transistor such as a 5-V breakdown-voltage MOS or a resistor are also connected to the substrate contact region 18. A wire 7 provided inside the insulating film 23 is connected to the substrate contact region 18 through a via 7a provided in a contact hole of the insulating film 23. The wire 7 is connected to the AGND pad 2 through a via 7b provided in a contact hole of the insulating film 23.

While FIG. 6 illustrates the case in which the wire 7 is arranged at the same layer as the lower-layer wiring layer 61, the wire 7 may be provided at the same layer as the upper-layer wiring layer 62. For example, the wire 7 and the upper-layer wiring layer 62 may be provided at the common layer so as to include the parts extending in parallel separately from each other in the horizontal direction.

As illustrated in FIG. 5 and FIG. 7, the AGND pad 2 and the PGND pad 3 are provided on the top surface side of the semiconductor base body 11 with an insulating film 9 interposed. The AGND pad 2 is connected to the PGND pad 3 through the bonding wire 35 and the bonding wire 36.

### Comparative Example

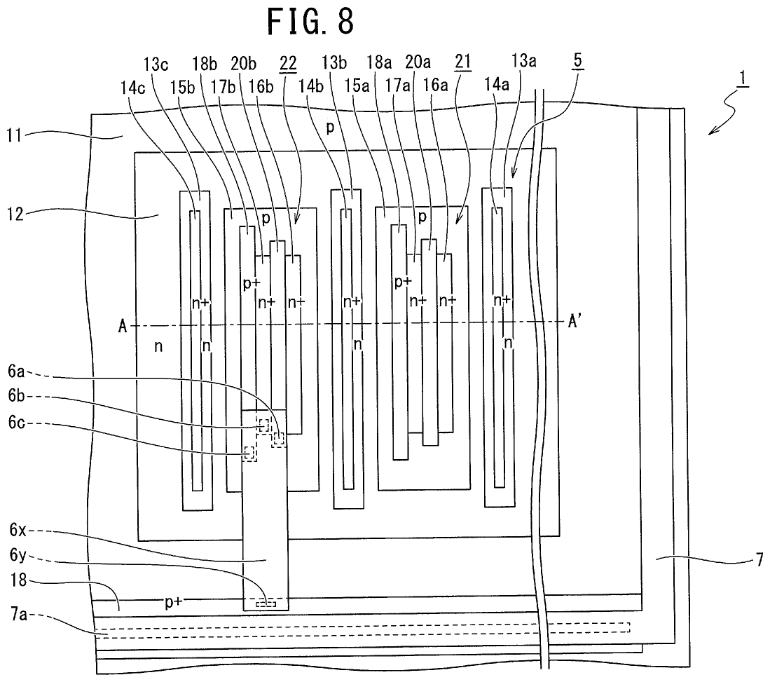

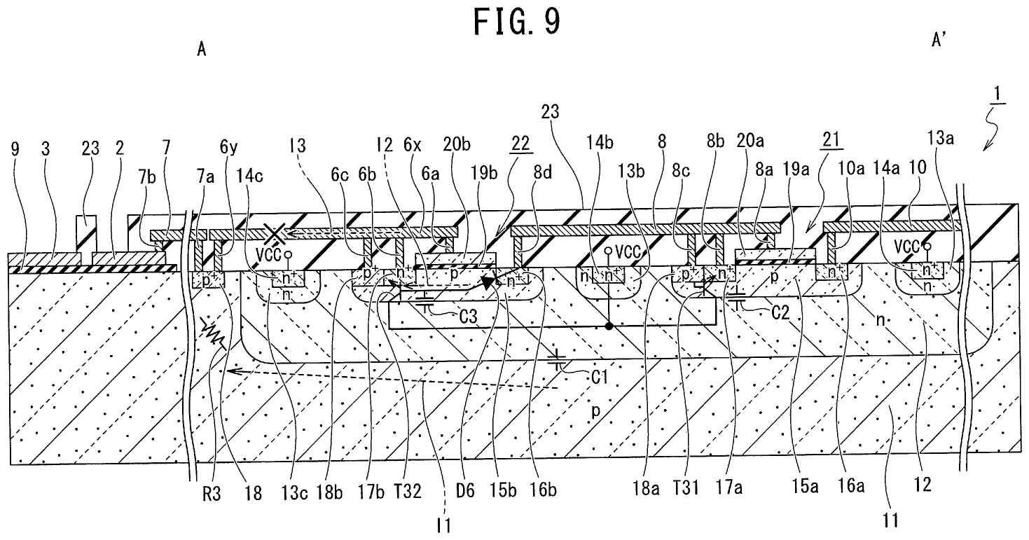

FIG. 8 illustrates a planar layout of a semiconductor chip 1 of a semiconductor device of a comparative example, and FIG. 9 is a cross-sectional view taken along line A-A′ in FIG. 8. As illustrated in FIG. 8 and FIG. 9, the semiconductor device of the comparative example differs from the semiconductor device according to the first embodiment illustrated in FIG. 5 to FIG. 7 in that the target to be connected with the gate electrode 20b, the source region 17b, and the contact region 18b of the transistor 22 at the fifth stage of the protection element 5 is not the AGND pad 2 but the p⁺-type substrate contact region 18. One end of a wire 6x is connected to the gate electrode 20b, the source region 17b, and the contact region 18b of the transistor 22 at the fifth stage through the vias 6a to 6c. The substrate contact region 18 is connected to the other end of the wire 6x through a via 6y. The gate electrode 20b, the source region 17b, and the contact region 18b of the transistor 22 at the fifth stage are thus indirectly connected to the AGND pad 2 via the substrate contact region 18.

The configuration of the semiconductor device of the comparative example may cause the protection element 5 to be turned ON because of a malfunction and thus lead to a flow of a large amount of current, which could result in breakage, since the source potential of the transistor 22 at the fifth stage of the protection element 5 rises when a timing at which the power-supply potential VCC applied to the VCC terminal 116 steeply increases due to a surge such as ESD or a high voltage overlaps with a timing at which the output-stage element T22 is turned ON.

More particularly, when the power-supply potential VCC applied to the VCC terminal 116 steeply increases, a displacement current I1 flows through the semiconductor base body 11, as illustrated in FIG. 9. The flow of the displacement current I1 leads to a rise of a substrate potential of the semiconductor base body 11 due to a resistance R3 of the semiconductor base body 11. The rise of the substrate potential of the semiconductor base body 11 is transferred to the substrate contact region 18. The steep increase of the power-supply potential VCC causes the displacement current to flow through a base of the parasitic npn bipolar transistor T32 via the parasitic capacitance C3, leading the parasitic npn bipolar transistor T32 to be turned ON.

At the same time, a current I0 instantaneously flows when the output-stage element T22 is in the ON-state to lead to a rise of the ground potential GND of the PGND pad 3, as schematically illustrated in FIG. 1. Since the PGND pad 3 and the AGND pad 2 are connected to each other at low impedance via the bonding wire 35, the bonding wire 36, and the GND terminal 117, the substrate contact region 18 connected to the AGND pad 2 rises up.

If the steep increase of the power-supply potential VCC applied to the VCC terminal 116 occurs simultaneously with the flow of the current I0 of the output-stage element T22, the potential of the well region 15b provided with the transistor 22 at the fifth stage connected to the substrate contact region 18 rises to go beyond a junction barrier between the drain region 16b and the well region 15b of the transistor 22 at the fifth stage. Further, the steep rise of the power-supply potential VCC causes the displacement current to flow through abase of the parasitic npn bipolar transistor T31 via the parasitic capacitance C2, leading the parasitic npn bipolar transistor T31 to be turned ON.

The parasitic npn bipolar transistor T31, when turned ON, leads to a rise of the source potential of the transistor 21 at the fourth stage, and the diode D6 implemented by the well region 15b and the drain region 16b are led to be in a reverse recovery state. This state causes an injection of a large amount of base current corresponding to a reverse recovery current I2 with respect to the parasitic npn bipolar transistor T32 to further lead a large amount of currents I3 to flow through the parasitic npn bipolar transistor T32, resulting in breakage accordingly.

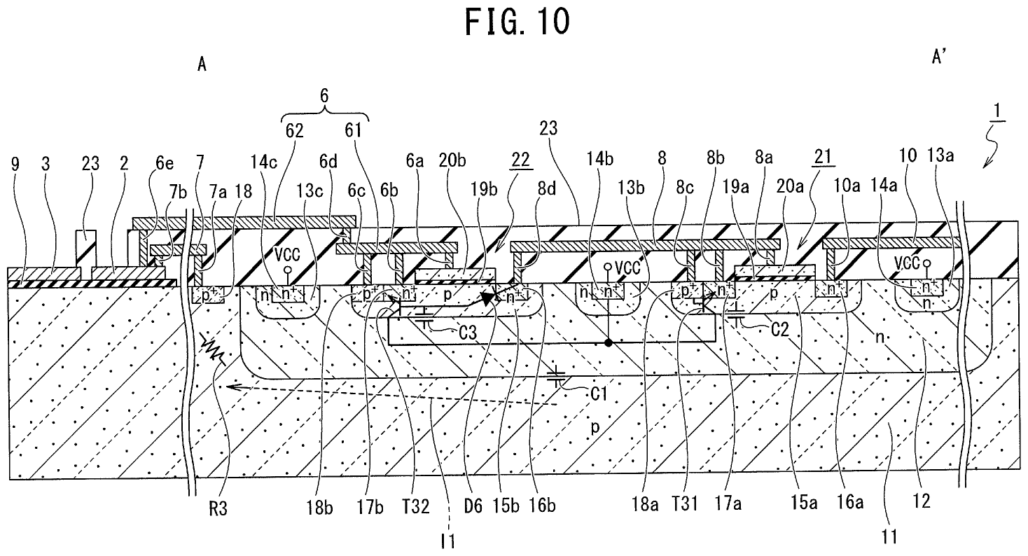

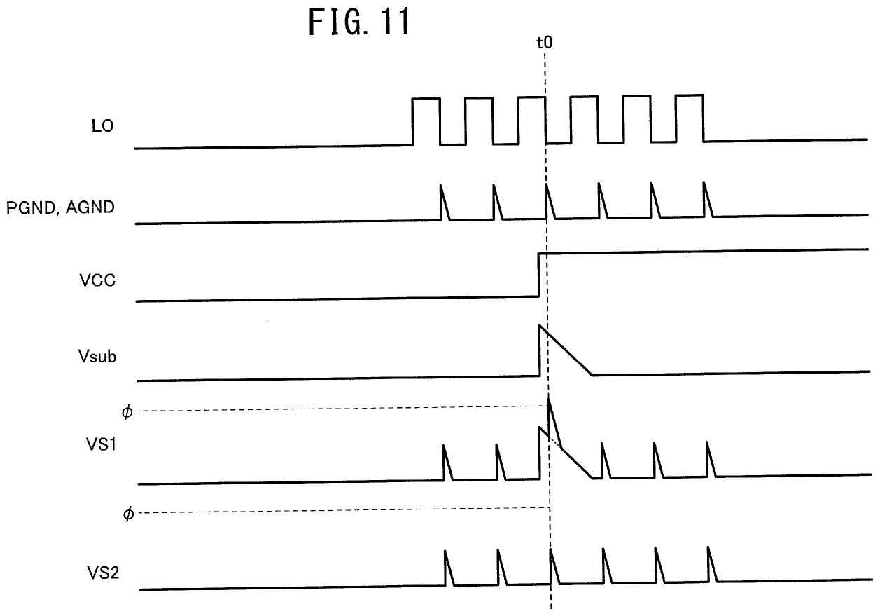

As compared with the comparative example, the semiconductor device according to the first embodiment has the configuration in which the gate electrode 20a, the source region 17a, and the contact region 18a of the transistor 21 at the fourth stage make a direct connection (linkage) with the AGND pad 2 without the substrate contact region 18 but by use of the wire 6, as illustrated in FIG. 10. This configuration can prevent the rise of the substrate potential of the semiconductor base body 11 due to the displacement current I1 from being transmitted to the source region 17b of the transistor 22 at the fifth stage if the steep increase of the power-supply potential VCC applied to the VCC terminal 116 is caused and overlaps with the timing of the ON state of the output-stage element T22, while allowing the transmission of the rise to the source region 17b of the transistor 22 at the fifth stage only by a potential corresponding to the rise of the PGND potential of the PGND pad 3, so as to suppress the excess of the junction barrier between the drain region 16b and the well region 15b of the transistor 22 at the fifth stage. This configuration thus can avoid the flow of the large amount of current caused by a malfunction of the protection element 5, so as to prevent damage accordingly.

Next, the respective operations of the semiconductor device according to the first embodiment and the semiconductor device of the comparative example are described below with reference to the timing chart shown in FIG. 11. The signs “LO”, “PGND, AGND”, “VCC”, and “Vsub” shown in FIG. 11 are used commonly for the semiconductor device according to the first embodiment and the semiconductor device of the comparative example. The sing “LO” corresponds to the drive signal LO applied to the LO terminal 114. The sign “PGND, AGND” corresponds to the amount of the rise of each of the ground potential GND of the PGND pad 3 and the ground potential GND of the AGND pad 2. The sign “VCC” corresponds to the power-supply potential VCC applied to the VCC terminal 116. The sing “Vsub” corresponds to the amount of the rise of the substrate potential of the semiconductor base body 11.

The sign “VS1” in FIG. 11 corresponds to the potential (the source potential) of the source region 17b of the transistor 22 at the fifth stage in the semiconductor device of the comparative example, and the sign “(” indicated above the sign “VS1” corresponds to the junction barrier between the drain region 16b and the well region 15b of the transistor 22 at the fifth stage. The sign “VS2” in FIG. 11 corresponds to the potential (the source potential) of the source region 17b of the transistor 22 at the fifth stage in the semiconductor device according to the first embodiment, and the sign “(” indicated above the sign “VS2” corresponds to the junction barrier between the drain region 16b and the well region 15b of the transistor 22 at the fifth stage.

When the potential “VCC” steeply increases immediately before time t0, the level “Vsub” rises. When the signal “LO” is led to a low level at time t0, the level “PGND, AGND” rises. The potential “VS1” in the semiconductor device of the comparative example rises by the total level of “Vsub” and “PGND, AGND”, which exceeds the junction barrier “(”. In contrast, the potential “VS2” in the semiconductor device according to the first embodiment has no influence by “Vsub” but rises only by the level “PGND, AGND”, which is below the junction barrier “(”.

### Second Embodiment

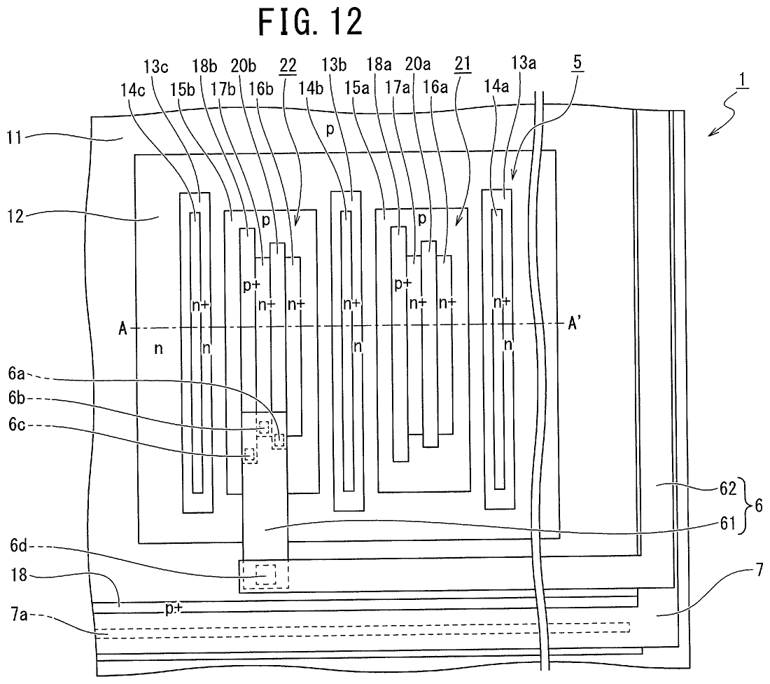

A semiconductor device according to a second embodiment differs from the semiconductor device according to the first embodiment illustrated in FIG. 6 in that the upper-layer wiring layer 62 of the wire 6 electrically connected to the gate electrode 20b, the source region 17b, and the contact region 18b of the transistor 22 at the fifth stage of the protection element 5 includes a part overlapping with the wire 7 electrically connected to the p⁺-type substrate contact region 18, as illustrated in FIG. 12.

The configuration of the semiconductor device according to the second embodiment can avoid a malfunction of the protection element 5 regardless of whether the steep increase of the power-supply potential VCC applied to the VCC terminal 116 is caused and overlaps with the timing of the ON state of the output-stage element T22, as in the case of the semiconductor device according to the first embodiment. Further, the semiconductor device according to the second embodiment having the configuration in which the upper-layer wiring layer 62 and the wire 7 are arranged to overlap with each other can contribute to a decrease in size of the semiconductor chip 1.

The semiconductor device according to the second embodiment may have a configuration in which the wire 7 and the lower-layer wiring layer 61 are provided at the same layer so that the upper-layer wiring layer 62 is arranged over the wire 7 and the lower-layer wiring layer 61. Alternatively, the wire 7 may be provided as a layer upper than the upper-layer wiring layer 62.

### OTHER EMBODIMENTS

As described above, the invention has been described according to the first and second embodiments, but it should not be understood that the description and drawings implementing a portion of this disclosure limit the invention. Various alternative embodiments of the present invention, examples, and operational techniques will be apparent to those skilled in the art from this disclosure.

While the respective semiconductor devices according to the first and second embodiments have been illustrated above with the switching power-supply circuit, the present invention can also be applied to other circuits instead of the switching power-supply circuit.

In addition, the respective configurations disclosed in the first and second embodiments can be combined together as appropriate without contradiction with each other. As described above, the invention includes various embodiments of the present invention and the like not described herein. Therefore, the scope of the present invention is defined only by the technical features specifying the present invention, which are prescribed by claims, the words and terms in the claims shall be reasonably construed from the subject matters recited in the present specification.

1. A semiconductor device comprising:
a semiconductor base body of a first conductivity-type;
a first well region of a second conductivity-type provided at an upper part of the semiconductor base body;
a protection element provided in the first well region and including transistors arranged at several stages each including a carrier supply region and a gate electrode mutually short-circuited;
a first pad provided on a top surface side of the semiconductor base body; and
a second pad provided on the top surface side of the semiconductor base body,
wherein a carrier reception region of the transistor at a frontmost stage included in the protection element is connected to the first pad, and the carrier supply region and the gate electrode of the transistor at a rearmost stage included in the protection element are connected to the second pad via a first wire.

2. The semiconductor device of claim 1, further comprising a substrate contact region of the first conductivity-type provided at the upper part of the semiconductor base body and connected to the second pad via a second wire.

3. The semiconductor device of claim 2, wherein the first wire includes a part extending parallel to the second wire as a common layer.

4. The semiconductor device of claim 2, wherein the first wire includes a part overlapping with the second wire as a different layer.

5. The semiconductor device of claim 1, further comprising a third pad provided on the top surface side of the semiconductor base body and electrically connected to the second pad.

6. The semiconductor substrate of claim 1, wherein the first pad is provided at a position closer to the protection element than the second pad.
